(19) United States
(12) Patent Application Publication
(10) Pub. No.: US 2003/0057456 A1
(43) Pub. Date: Mar. 27, 2003

(54) Semiconductor optical modulator and optical modulator integrated semiconductor laser

(76) Inventor: Hiroshi Wada, Tokyo (JP)

Correspondence Address: WENDEROTH, LIND & PONACK, L.L.P., 2033 K STREET N. W., SUITE 800, WASHINGTON, DC, 20006-1021, US

(21) Appl. No.: 10/254,527

(22) Filed: Sep. 26, 2002

(30) Foreign Application Priority Data
Sep. 26, 2001 (JP) 293901/2001

(51) Int. Cl. H01L 27/148

(52) U.S. Cl. 257/222

(57) ABSTRACT

An electrode-absorption semiconductor optical modulator has a lower clad layer formed on a semiconductor substrate, an optical absorption layer for absorbing light formed on the lower clad layer, and an upper clad layer formed on the optical absorption layer. The electrode-absorption semiconductor optical modulator further includes a first electrode formed on a first main surface of the upper clad layer and a second electrode formed on a second main surface of the semiconductor substrate side. The first electrode is separated along a light proceeding direction entered from a light incident side end face of the optical modulator and the plurality of electrodes apply voltages.

### BACKGROUND OF THE INVENTION

The present invention relates to an electro absorption (EA) semiconductor optical modulator element (hereinafter, referred to as EA modulator) and an EA modulator integrated semiconductor laser used as a light source for, for example, a high speed optical communication and an optical information processing system.

An EA modulator is an element for converting an electric signal with a high speed into an optical signal by using change of a light absorption ratio on a semiconductor light absorption layer by a voltage to be applied between a first electrode formed at an upper part of an upper clad and a second electrode formed on a rear face of a semiconductor substrate from the outside.

FIG. 1 is a conventional structure model view of an EA modulator. An absorption ratio of an absorption layer is changed by applying a reverse bias voltage between an electrode I and an electrode II in FIG. 1, as a result, a permeability ratio of an incident light (ratio of emitting light intensity to incident light intensity) is changed. As a basic structure of the absorption layer, multi quantum well (MQW) layers or bulk layers are used.

As mechanism for changing by the voltage to which the absorption ratio is applied, stark effect to trap quantum or franz keldysh effect is used. These are disclosed in a reference of “LEADING END OPTICAL ELECTRONICS SERIES 4, ULTRA SPEED OPTICAL

DEVICE (FUJIRO SAITO, KYORITSU PUBLISHING), 6^{th} chapter, pages 128 to 134” in detail.

FIG. 2 shows an operation of an EA modulator. In this drawing, the absorption ratio of light and wavelength of light are respectively shown at an ordinate and at an abscissa. Generally, the longer the wavelength is the more the absorption ratio lowers. Specially, the absorption ratio is abruptly reduced when the absorption ratio exceeds wavelength called as an absorption end. The absorption end is determined by a band gap of the absorption layer. When the reverse bias voltage is applied to the absorption layer from the outside, the absorption end is shifted to the long wavelength side as shown in FIG. 2. As a result, this increases the absorption ratio for any incident light wavelength (generally, incident light wavelength is set to the long wavelength side from absorption end wavelength). The EA modulator is a device for modulating emitting light intensity at a high speed by using this principle.

Problem accompanying the conventional EA modulator will be described referring to FIGS. 3A and 3B. As shown in FIG. 3A, according to the conventional structure, incident light entering from a left side end face is continuously absorbed according to proceeding of light entered from the left side end face to the right side in an absorption layer of an EA modulator. As a result, light intensity around left side end face is the highest and light intensity gradually lowers according to the right side as shown in FIG. 3B. In response to this, a photocurrent around left side incident end face is also the highest and the photocurrent gradually lowers according to the right side in the absorption layer. The photocurrent is generated in each part.

At this time, the higher the photocurrent flows into a local part in the EA modulator, the higher at the temperature the local part therein. Temperature around left side incident end face is also the highest and temperature gradually lowers according to the right side in the absorption layer as shown in FIG. 3B. Generally, maximum light intensity (hereinafter, referred to as maximum absolute rating), which can be entered in the EA modulator is determined by temperature increase at the local part in the EA modulator. Usually, maximum optical intensity is determined at an operational point where temperature around left side incident end face where temperature increase is the highest (optical signal incident end face) becomes temperature to limit to the fusion of crystallization, which constitutes the light incident end face. Therefore, there is a problem that when temperature increase in the EA modulator is not uniform as described above, light intensity reaches maximum absolute rating at lower level to enter light.

### SUMMARY OF THE INVENTION

The present invention may provide a means for raising the maximum optical intensity, which can be entered by various methods so that temperature increase distribution in an EA modulator can be more uniform.

According to the present invention, an electrode-absorption semiconductor optical modulator having a lower clad layer formed on a semiconductor substrate, an optical absorption layer for absorbing light formed on the lower clad layer, and an upper clad layer formed on the optical absorption layer, includes a first electrode formed on a first main surface of the upper clad layer; and a second electrode formed on a second main surface of the semiconductor substrate side, in which the first electrode is separated along a light proceeding direction entered from a light incident side end face of the optical modulator and the plurality of electrodes apply voltages.

The summary of the invention does not necessarily describe all necessary features of the present invention. The present invention may also be a sub-combination of the features described above. The above and other features and advantages of the present invention will become more apparent from the following description of the embodiments taken in conjunction with the accompanying drawings.

### BRIEF DESCRIPTION OF THE DRAWINGS

FIG. 1 is a schematic structure model view of a conventional EA modulator.

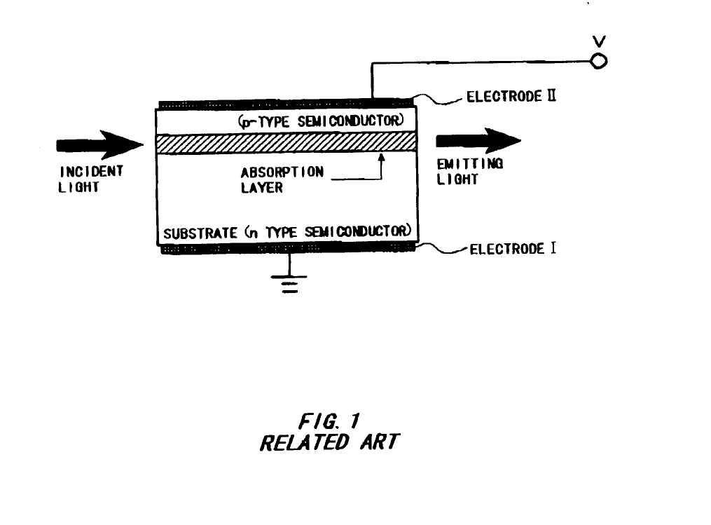

FIG. 2 is a graph for explaining an operation of an EA modulator.

FIGS. 3A and 3B are views showing the conventional EA modulator's operational principle.

FIG. 4 is a schematic structure model view of an EA modulator in the present invention.

FIGS. 5A and 5B are views showing EA modulator's operational principle according to the invention.

FIG. 6 is a structure model view of an EA modulator in the present invention.

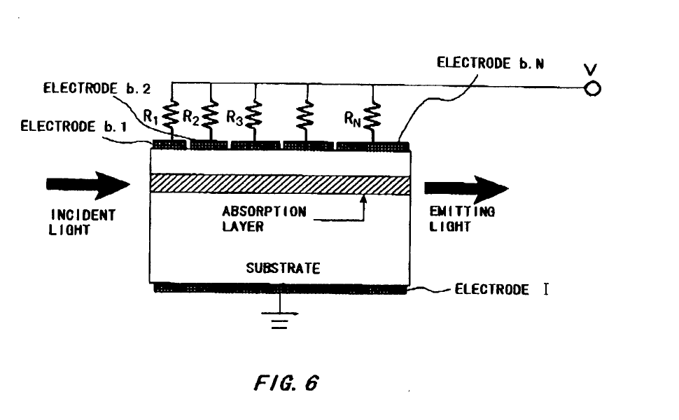

FIG. 7 is a structure model view of an EA modulator in the present invention.

FIG. 8 is a structure model view of an EA modulator in the present invention.

### DETAILED DESCRIPTION OF THE INVENTION

The invention will now be described based on preferred embodiments, which do not intend to limit the scope of the present invention, but rather to exemplify the invention. All of the features and the combinations thereof described in the embodiments are not necessarily essential to the invention.

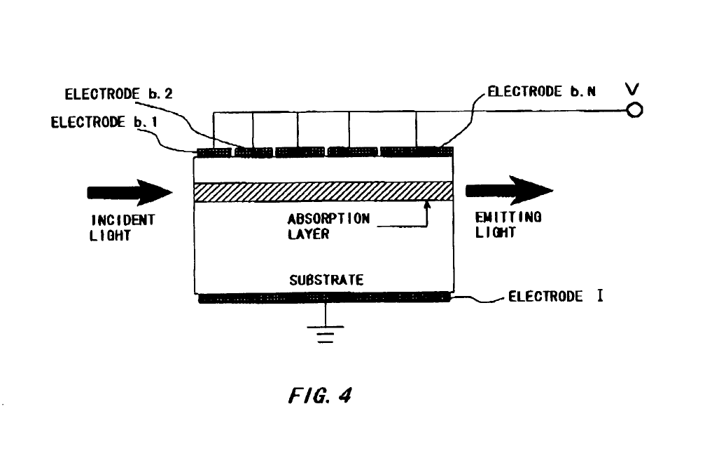

FIG. 4 shows a structure of an EA modulator according to the present invention. A main feature is that a plurality of different electrodes separated from one another are formed along is a light propagating direction. Light is absorbed by applying reverse bias to each of the electrodes. Absorbed light is transformed into a current and the transformed light becomes a photocurrent.

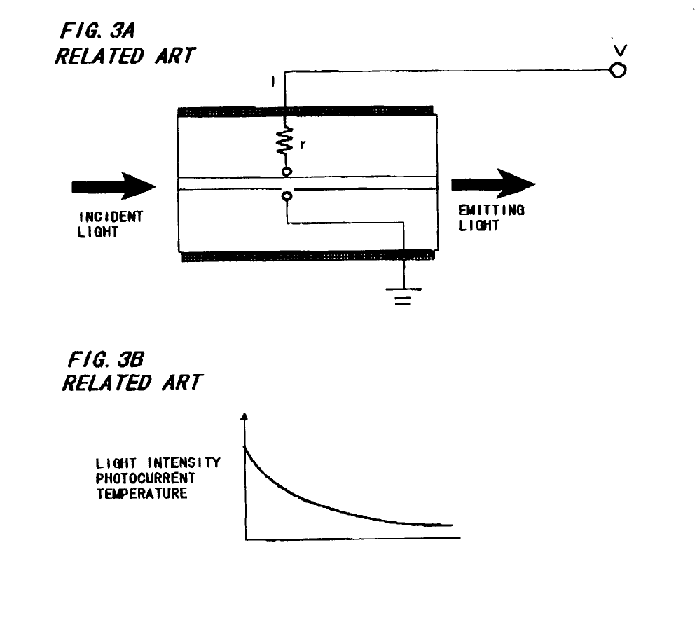

An operation of resistance r in a conventional EA modulator of FIG. 3A will be described. Conventionally, since the entire absorption layer in an EA modulator shares one electrode, it is almost deemed that the entire absorption layer is connected to a power supply via one resistance r as shown in FIG. 3A. When light enters from the outside and a photocurrent I is flown into a connection, a reverse bias voltage Vi applied to the absorption layer is represented by the following formula (1):

Vi=V−I×r (1)

The higher the photocurrent I, and the higher the resistance r, the reverse bias applied to the absorption layer is lower than a voltage V applied from the outside.

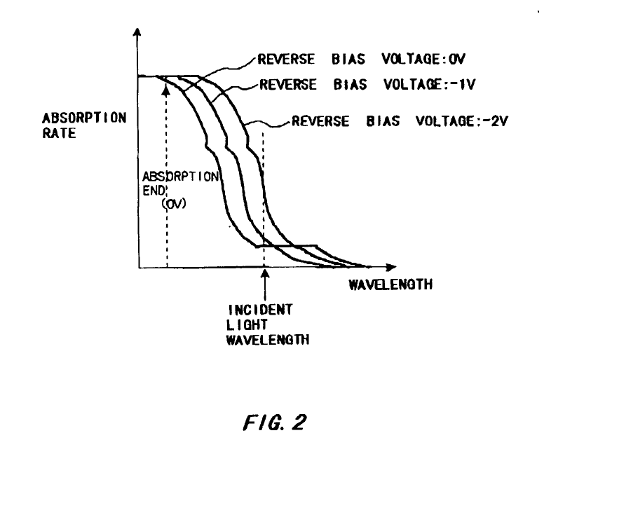

As seen from FIG. 2, the lower the reverse bias is applied to the absorption layer, the lower the coefficient of light's absorption is. Generally, when resistance exits between the absorption layer and an external power supply, an external voltage becomes lower by this resistance. Thereby, the lower voltage than the external voltage is just applied to the absorption layer. Therefore, only lower absorption coefficient can be obtained in comparison with an absorption coefficient supposed from the external voltage value (absorption coefficient of a case where r is 0). In a conventional structure in FIG. 3A and FIG. 3B, since the entire absorption layer is connected to the power supply via one resistance r, there is almost no independency of an area in this effect.

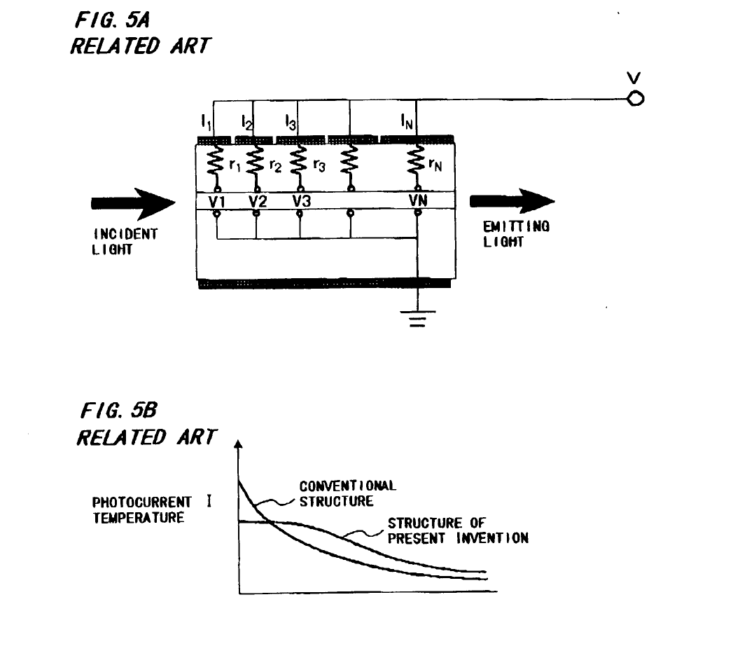

FIGS. 5A and 5B are views showing EA modulator's operational explanation in the present invention. Since the electrode is separated into the plurality of electrodes as different from the prior art of FIGS. 3A and 3B, each of parts is connected to the external power supply via independent resistance ri. When light is entered from the outside and a photocurrent Ii is flown into a connection, a reverse bias voltage Vi applied to the absorption layer of each connection is represented by the following formula (2):

Vi=V−Ii×ri (2)

If length of the separated electrode is constant and ri is constant in each part, the higher the photocurrent Ii close to a light incident end face, the lower voltage of a reverse bias applied to the absorption layer than a voltage V applied from the outside. Therefore, in FIG. 2, the higher the photocurrent close to the light incident end face, the lower the absorption coefficient in a part of the higher photocurrent. Distribution of the photocurrent can be lower than a photocurrent of a conventional structure as shown in FIG. 5B. As a result, temperature distribution can be lowered and maximum light intensity (absolute rating), which is capable of entering light can be high.

As obvious from the above, the reverse bias voltage Vi depends on the resistance ri and, therefore, it the reverse bias voltage vi is set so that electrode length is short according to close to the light incident end face and electrode length is gradually long according to the distance from the light incident end face, distribution of the photocurrent can further be lowered and absolute rating can be high.

A second embodiment proposes an EA modulator in which a resistance Ri having each of independent resistance values is provided between each of the separated electrodes and an external power supply in the EA modulator of the plurality of electrodes as described in a first embodiment (See FIG. 3A).

According to the present embodiment, since the resistance Ri can be set to any values, uniformity of temperature distribution exemplary shown in FIG. 5B can freely be designed highly. As a result, temperature distribution can be low and maximum light intensity (absolutely rating), capable of entering light can be higher than temperature distribution and maximum intensity in the first embodiment.

This effect is commonly applied also when length of each separated electrode is constant or length of each separated electrode is set to different length.

An example to integrate semiconductor laser in the EA modulator having the plurality of electrodes in the first embodiment will be described in a third embodiment.

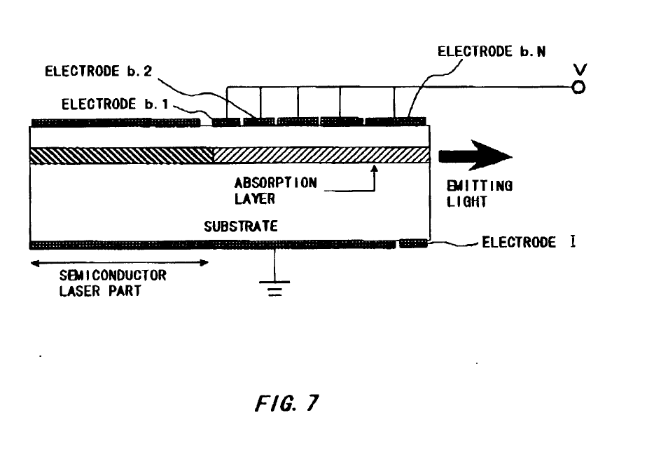

Semiconductor laser, which is a source, is integrated with the EA modulator rather than light is entered into the EA modulator from the outside, and thereby cost and power consumption can be reduced. A structural view of the aforementioned case is shown in FIG. 7. This semiconductor laser may be a laser, which exits laser beam with predetermined wavelength (e.g., DFB laser) or a wavelength variable laser, which is recently widely used as a light source for a WDM system.

A structure shown in FIG. 7 enables an EA modulator integrated semiconductor laser with maximum optical intensity to be realized similar to the first embodiment.

In a fourth embodiment, an example to integrate semiconductor laser into an EA modulator will be described. The EA modulator is similar to the modulator of the second embodiment but has a plurality of electrodes and a resistance disposed at an outside thereof.

FIG. 5A shows a structural view of the present embodiment. This semiconductor laser may be a laser, which emits laser beam with a single, certain wavelength (e.g., DFB laser) or a wavelength variable laser, which is recently widely used as a light source for a WDM system.

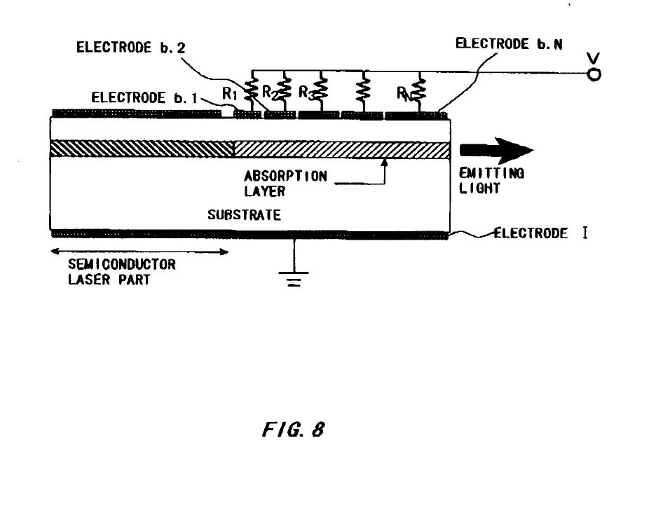

A structure depicted in FIG. 8 realizes an EA modulator integrated semiconductor laser with maximum beam intensity similar to the third embodiment.

Although the present invention has been described by way of exemplary embodiments, it should be understood that those, skilled in the art might make many changes and substitutions without departing from the spirit and the scope of the present invention which is defined only by the appended claims.

What is claimed ts:

1. An electrode-absorption semiconductor optical modulator having a lower clad layer formed on a semiconductor substrate, an optical absorption layer for absorbing light formed on said lower clad layer, and an upper clad layer formed on said optical absorption layer, comprising:
a first electrode formed on a first main surface of said upper clad layer; and
a second electrode formed on a second main surface of said semiconductor substrate side, wherein said first electrode is separated along a light proceeding direction entered from a light incident side end face of said optical modulator and said plurality of electrodes apply voltages.

2. An electrode-absorption semiconductor optical modulator as claimed in claim 1, wherein each of said electrodes is formed so that length of said electrode, of the closest part to said light incident side end face, for applying the voltage is the shortest and length of each of said electrodes to apply said voltage is gradually long according to said light proceeding direction entered from said light incident side end of said optical modulator.

3. An electro-absorption semiconductor optical modulator as claimed in claim 1, wherein a resistance having a different resistance value is formed between each of said plurality of separated electrodes for applying said voltage and an external power supply connected to each of said electrodes.

4. An electro-absorption semiconductor optical modulator as claimed in claim 2, wherein a resistance having a different resistance value is formed between each of said plurality of separated electrodes for applying said voltage and an external power supply connected to each of said electrodes.

5. An optical modulator integrated semiconductor laser comprising:
an electrode-absorption semiconductor optical modulator having a lower clad layer formed on a semiconductor substrate, an optical absorption layer for absorbing light formed on said lower clad layer, and an upper clad layer formed on said optical absorption layer, the electrode-absorption semiconductor optical modulator including,
a first electrode formed on a first main surface of said upper clad layer, and
a second electrode formed on a second main surface of said semiconductor substrate side, wherein said first electrode is separated along a light proceeding direction entered from a light incident side end face of said optical modulator and said plurality of electrodes apply voltages; and
a semiconductor laser integrated with the electro-absorption semiconductor optical modulator.

6. An optical modulator integrated semiconductor laser as claimed in claim 5, wherein each of said electrodes is formed so that length of said electrode, of the closest part to said light incident side end face, for applying the voltage is the shortest and length of each of said electrodes to apply said voltage is gradually long according to said light proceeding direction entered from said light incident side end of said optical modulator.

7. An optical modulator integrated semiconductor laser as claimed in claim S, wherein a resistance having a different resistance value is formed between each of said plurality of separated electrodes for applying said voltage and an external power supply connected to each of said electrodes.

8. An optical modulator integrated semiconductor laser as claimed in claim 6, wherein a resistance having a different resistance value is formed between each of said plurality of separated electrodes for applying said voltage and an external power supply connected to each of said electrodes.
